(19) United States
(12) Patent Application Publication
(10) Pub. No.: US 2019/0057982 A1
(43) Pub. Date: Feb. 21, 2019

(54) FLEXIBLE DISPLAY AND IMPROVING METHOD AND IMPROVING DEVICE OF BENDING DISPLAY ABNORMALITY THEREOF

(71) Applicant: Shenzhen China Star Optoelectronics Semiconductor Display Technology Co., Ltd., Shenzhen, Guangdong (CN)

(72) Inventors: Tai-jun HWANG, Shenzhen, Guangdong (CN); Pengfei LIANG, Shenzhen, Guangdong (CN)

(73) Assignee: Shenzhen China Star Optoelectronics Semiconductor Display Technology Co., Ltd., Shenzhen, Guangdong (CN)

(21) Appl. No.: 15/750,184

(22) PCT Filed: Sep. 13, 2017
(86) PCT No.: PCT/CN2017/101543

§ 371 Date: Feb. 3, 2018

(30) Foreign Application Priority Data
Aug. 18, 2017 (CN) 201710709582.4

(51) Int. Cl. H01L 27/12; H01L 51/00; H01L 51/52; G09G 3/3258

(52) U.S. Cl. CPC H01L 27/1214; H01L 51/0097; G09G 2310/08; H01L 51/5221; G09G 3/3258; H01L 51/5206

(57) ABSTRACT

The disclosure discloses an improving method of bending display abnormality of a flexible display, including the following steps: detecting a characteristic parameter of a driving thin film transistor of each of pixels in the flexible panel during display bending; calculating a bending position of the flexible panel according to the characteristic parameter of the driving thin film transistor of each of pixels; performing image visual correction on an image displayed by the pixels located at the bending position of the flexible panel. The disclosure also discloses an improving device of display bending abnormality of a flexible display and a flexible display. In the disclosure, when the flexible display is displayed in a bent state, the pixels located at the bending position are corrected to improve the display abnormality, thereby enhancing the display quality.

### RELATED APPLICATIONS

The present application is a National Phase of International Application Number PCT/CN2017/101543, filed Sep. 13, 2017, and claims the priority of China Application No. 201710709582.4, filed Aug. 18, 2017.

### FIELD OF THE DISCLOSURE

The disclosure relates to the field of flexible display technology, in particular to a flexible display and an improving method and an improving device of bending display abnormality thereof. The disclosure relates to a display technical field, and more particularly to a display panel and a display device.

### BACKGROUND

In recent years, Organic Light-Emitting Diode (OLED) display panel has become a very popular and emerging flat panel display product at home and abroad because the OLED display panel has the advantages such as self-luminous, wide viewing angle, short response time, high luminous efficiency, wide color gamut, thin thickness, and it can be generated in large size and flexible display panel, and not only the manufacturing process is simple but also it has the potential of low cost.

In a flexible display using an OLED display panel, when the flexible display is in a bent state, both the threshold voltage and the intrinsic conductance factor of the driving thin film transistor of OLED at bending may change, thereby resulting in the change of driving current of OLED; in addition, the visual difference caused by the superimposed bending causes the display of the flexible display to be abnormal.

### SUMMARY

To solve the problems of the prior art, the object of the disclosure is to provide a flexible display for improving display abnormality during bending and an improving method and an improving device of bending display abnormality thereof.

According to an aspect of the disclosure, there is provided an improving method of bending display abnormality of a flexible display, including the following steps: detecting a characteristic parameter of a driving thin film transistor of each of pixels in the flexible panel during display bending; calculating a bending position of the flexible panel according to the characteristic parameter of the driving thin film transistor of each of the pixels; and performing image visual correction on an image displayed by the pixels located at the bending position of the flexible panel and correcting the characteristic parameter of the driving thin film transistor of the pixels located at the bending position of the flexible panel.

Further, a specific method of implementing the step of “performing image visual correction on an image displayed by the pixels located at the bending position of the flexible panel” includes: performing image sharpening processing on the image displayed by the pixels located at the bending position of the flexible panel.

Further, a specific method for implementing the step of “correcting the characteristic parameter of the driving thin film transistor of the pixels located at the bending position of the flexible panel” includes: correcting the mobility and/or a channel width-to-length ratio and/or an equivalent capacitance of the driving thin film transistor of the pixels located at the bending position of the flexible panel.

Further, a specific method for implementing the step of “detecting a characteristic parameter of a driving thin film transistor of each of pixels in the flexible panel during display bending” comprises: detecting a gate voltage and/or a mobility of a driving thin film transistor of each of the pixels in the flexible panel during display bending.

According to another aspect of the disclosure, there is provided an improving device of display abnormal bending of a flexible display, including: a detecting module, configured to detect a characteristic parameter of a driving thin film transistor of each of pixels in the flexible panel during display bending; a bending position calculating module, configured to calculate a bending position of the flexible panel according to the characteristic parameter of the driving thin film transistor of each of the pixels; a processing module, configured to perform an image visual correction on the image displayed by the pixels located at the bending position of the flexible panel and to correct the characteristic parameter of the driving thin film transistor of the pixels located at the bending position of the flexible panel.

Further, the processing module is further configured to perform image sharpening processing on the image displayed by the pixels located at the bending position of the flexible panel.

Further, the processing module is further configured to correct a mobility and/or a channel width-to-length ratio and/or an equivalent capacitance of the driving thin film transistor of the pixels located at the bending position of the flexible panel.

Further, the detecting module is further configured to detect a gate voltage and/or a mobility of a driving thin film transistor of each of the pixels in the flexible panel during display bending.

Accordingly, further another aspect of the disclosure further provides a flexible display including: a flexible panel including a plurality of pixels, and the plurality of pixels including a driving thin film transistor and an organic light emitting diode connected to the driving thin film transistor; a power voltage generator, configured to provide a positive power voltage to the driving thin film transistor and to provide a negative power voltage to the organic light emitting diode; the improving device described above, configured to correct the plurality of pixels at the bending position of the flexible panel so as to generate a correction signal when the bending of the display of a flexible panel is performed; a timing controller configured to correct a scan control signal and a data control signal generated by the timing controller according to the correction signal; a scan driver, configured to generate a corrected scan voltage based on the corrected scan control signal and to supply the corrected scan voltage to the pixel; and a data driver, configured to generate a corrected data voltage based on the corrected data control signal and to supply the correction data voltage to the plurality of pixels.

Optionally, the pixels further include a second thin film transistor, a third thin film transistor, a storage capacitor, a read line, and a switch control line; a source of the driving thin film transistor is connected to an anode of an organic light emitting diode, a drain of the driving thin film transistor is connected to the power voltage generator to receive the positive power voltage; a gate of the driving thin film transistor is connected to a drain of the second thin film transistor; a cathode of the organic light emitting diode is connected to the power voltage generator to receive a negative power voltage; a gate of the second thin film transistor is connected to a scan line, and a source of the second thin film transistor is connected to a data line; the storage capacitor is connected between the source and the gate of the driving thin film transistor; and a gate of the third thin film transistor is connected to the switch control line, a source of the third thin film transistor is connected to the read line, a drain of the third thin film transistor is connected to a source of the first thin film transistor, and the read line is connected to the improving device.

The beneficial effect of the disclosure is that when the flexible display is displayed in a bent state, the plurality of pixels at the bending positions are corrected to improve the display abnormality, thereby enhancing the display quality.

### BRIEF DESCRIPTION OF THE DRAWINGS

The forgoing and other objects, features, and advantages of the disclosure will become more fully apparent from the following detailed description of the embodiment, the appended claims and the accompanying drawings in which:

FIG. 1 is a schematic structural view of a flexible display according to an embodiment of the disclosure;

FIG. 2 is a circuit configuration diagram of one of the pixels according to an embodiment of the disclosure;

FIG. 3 is a flow chart of an improving method of bending display abnormality of a flexible display according to an embodiment of the disclosure.

### DETAILED DESCRIPTION OF PREFERRED EMBODIMENTS

Hereinafter, embodiments of the disclosure will be described in detail with reference to the accompanying drawings. This disclosure may, however, be embodied in many different forms and should not be construed as limited to the embodiments set forth herein. Rather, these embodiments are provided to explain the principles of the disclosure and its practical application so as to enable those skilled in the art to understand the various embodiments of the disclosure and various modifications that are suitable for a specific intended application.

In the drawings, the thickness of the layers and regions is exaggerated in order to clarify the device. The same reference numerals refer to like elements throughout the specification and drawings.

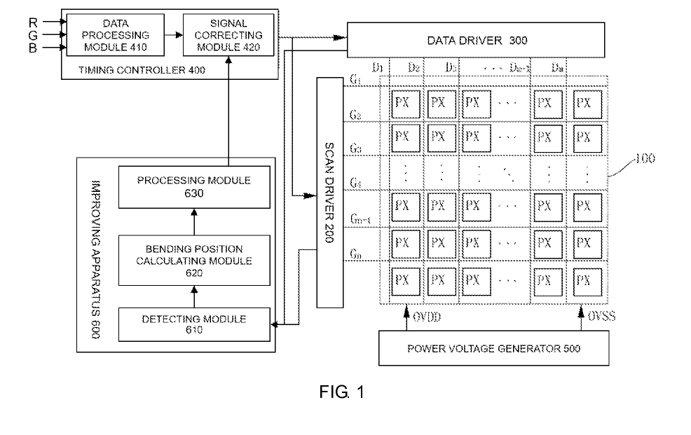

FIG. 1 is a schematic structural view of a flexible display according to an embodiment of the disclosure;

Referring to FIG. 1, a flexible display according to an embodiment of the disclosure includes a flexible panel 100, a scan driver 200, a data driver 300, a timing controller 400, a power voltage generator 500, and an improving device 600.

Specifically, a flexible panel 100 includes a plurality of pixels PX, and the plurality of pixels PX are connected to the display signal lines. The display signal lines may include a plurality of scan lines G₁ to Gₙ configured to transmit a scan voltage and a plurality of data lines D₁ to Dₘ configured to transmit a data voltage. The scan lines G₁ to Gₙ extend in a row direction and are substantially parallel to each other, and the data lines D₁ to Dₘ extend in the column direction and are substantially parallel to each other.

The scan driver 200 is connected to the plurality of scan lines G₁ to Gₙ, and applies a scan voltage to the plurality of scan lines G₁ to Gₙ. The scan voltage supplies to the plurality of pixels PX through the plurality of scan lines G₁ to Gₙ.

The data driver 300 is connected to the plurality of data lines D₁ to Dₘ, and applies the data voltage of the plurality of data lines D₁ to Dₘ. The data voltage supplies to the plurality of pixels PX through the plurality of data lines D₁ to Dₘ.

The timing controller 400 controls the operations of the scan driver 200 and the data driver 300.

The timing controller 400 receives image signals (such as R, G, and B signals) from an external graphics controller (not shown). The timing controller 400 appropriately processes the image signals to generate the scan control signal and the data control signal. Then, the timing controller 400 transmits the scan control signal to the scan driver 200 and transmits the data control signal to the data driver 300.

The scan driver 200 generates a scan voltage in response to a scan control signal and applies a scan voltage to the plurality of scan lines G₁ to Gₙ. The data driver 300 generates a data voltage in response to the data control signal and applies the data voltage to the plurality of data lines D₁ to Dₘ.

The power voltage generator 500 generates a positive power voltage OVDD and a negative power voltage OVSS, and supplies the positive power voltage OVDD and the negative power voltage OVSS to the plurality of pixels PX.

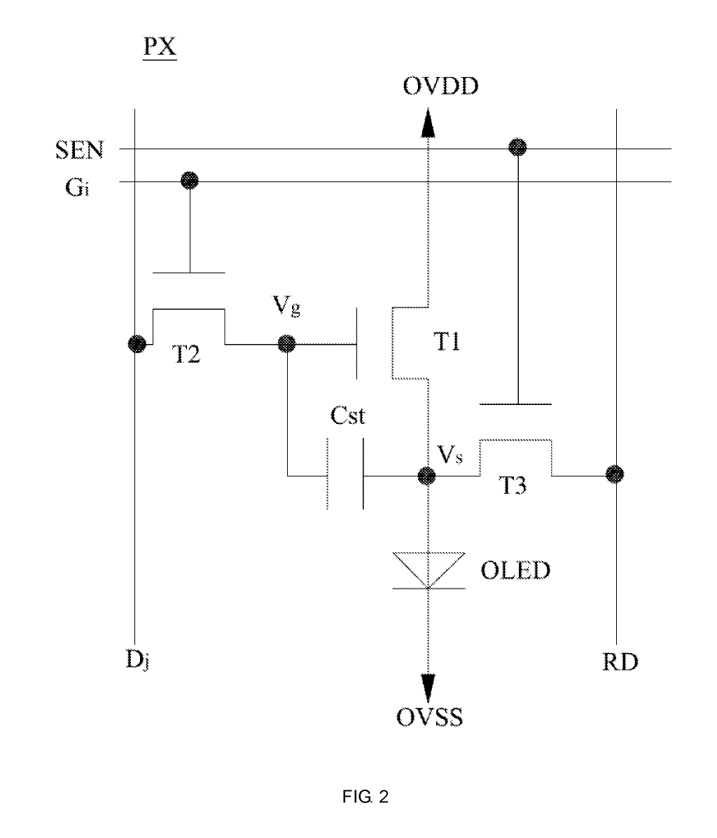

FIG. 2 is a circuit configuration diagram of one of the pixels according to an embodiment of the disclosure.

Referring to FIG. 2, each of the pixels PX according to an embodiment of the disclosure includes: a first thin film transistor (or called driving thin film transistor) T1, a second thin film transistor T2, a third thin film transistor T3, a storage capacitor Cst, an organic light emitting diode OLED, a read line RD, and a switch control line SEN.

A source of the first thin film transistor T1 is connected to the anode of the organic light emitting diode OLED; a drain of the first thin film transistor T1 is connected to the power voltage 500, to receive the positive power voltage OVDD; a gate of the first thin film transistor T1 is connected to a drain of the second thin film transistor T2; a cathode of the organic light emitting diode OLED is connected to the power voltage generator 500 to receive a negative power voltage OVSS; the gate of the second thin film transistor T2 is connected to the scan line Gᵢ (1≤i≤n), and the source thereof is connected to the data line Dⱼ (1≤j≤m); the storage capacitor Cst is connected between the source and the gate of the first thin film transistor T1; a gate of the third thin film transistor T3 is connected to the switch control line SEN, a source of the third thin film transistor T3 is connected to the read line RD, a drain of the third thin film transistor T3 is connected to a source of the first thin film transistor T1, and the read line RD is connected to the improving device 600 so as to make the improving device 600 read a characteristic parameter of the first thin film transistor T1 of each of the pixels PX through the read line RD.

In addition, the switch control line SEN may control whether the third thin film transistor T3 is turned on or not. When the third thin film transistor T3 is turned on, the improving device 600 reads the characteristic parameter of the first thin film transistor T1 of the pixels PX through the read line RD and the turned-on third thin film transistor T3.

Referring to FIGS. 1 and 2, when the flexible display performs bending display according to an embodiment of the disclosure, the improving device 600 performs correction of the plurality of pixels PX at the bending position and generates a correction signal.

Further, the improving device 600 according to the embodiment of the disclosure includes: a detecting module 610, a bending position calculating module 620, and a processing module 630.

The detecting module 610 is configured to detect the characteristic parameter of the first thin film transistor T1 of each of the plurality of pixels PX in the flexible panel 100 when the bending display is performed. Specifically, the detecting module 610 is configured to detect the gate voltage and/or the mobility of the first thin film transistor T1 of each of the plurality of pixels PX in the flexible panel 100 during display bending.

A bending position calculating module 620 is configured to calculate a bending position of the flexible panel according to the characteristic parameter (that is, the gate voltage and/or the mobility detected by detecting module 610) of the first thin film transistor T1 of each of the plurality of pixels PX.

A processing module 630 is configured to perform image visual correction on the image displayed by the plurality of pixels PX located at the bending position of the flexible panel 100 and to correct the characteristic parameter of the first thin film transistor T1 of the plurality of pixels PX located at the bending position of the flexible panel 100. Specifically, the processing module 630 performs image sharpening processing on the image displayed by the plurality of pixels PX located at the bending position of the flexible panel 100, and the processing module further corrects the mobility and/or the channel width-to-length ratio and/or the equivalent capacitance of the first thin film transistor T1 of the plurality of pixels PX located at the bending position of the flexible panel 100, and generates a correction signal carrying the image visual correction information and the correction signal of the correction information according to the characteristic parameter of the first thin film transistor T1.

The driving current of the organic light-emitting diode OLED is I₁=k(V_{sg}−Vₜₕ)²=k(Vₛ−V_{g}−Vₜₕ)²=k(OVDD−V_{g}−Vₜₕ)², k is an intrinsic conductance factor of the first thin film transistor T1, determined by the own characteristics of the first thin film transistor T1; and Vₜₕ is a threshold voltage of the first thin film transistor T1, Vₛ is a source voltage of the first thin film transistor T1, and V_{g} is a gate voltage of the first thin film transistor T1.

And

$$k = \frac{1}{2} U * COX * \frac{W}{L} ,$$

here, U represents a mobility of the first thin film transistor T1, COX represents an equivalent capacitance, W represents a channel width of the first thin film transistor T1, and L represents a channel length of the first thin film transistor T1.

As described in the prior art, when the flexible display is in a bent state, both the threshold voltage Vₜₕ and the intrinsic conductance factor k of the first thin film transistor T1 of the plurality of pixels PX at the bending position may change, thereby making the driving current of the organic light emitting diode OLED be changed. In order to ensure that the driving current of the organic light emitting diode OLED is unchanged, in this embodiment, the correction of the mobility U and/or the channel width-to-length ratio W/L and/or the equivalent capacitance COX of the first thin film transistor T1 of the plurality of pixels PX located at the bending position of the flexible panel 100 is performed by the processing module 630, thereby making the driving current I₁ of the organic light emitting diode OLED be unchanged.

In addition, as described in the prior art, the image displayed by the plurality of pixels PX located at the bending position may have a visual difference such as image stretching. In order to eliminate the visual difference, in this embodiment, the processing module 630 performs image sharpening processing on the image displayed by the plurality of pixels PX located at the bending position of the flexible panel 100 to eliminate the visual difference.

The timing controller 400 receives the correction signal, and corrects the scan control signal and the data control signal generated by the timing controller 400 according to the correction signal.

Further, the timing controller 400 according to the embodiment of the disclosure includes: a data processing module 410 and a signal correcting module 420.

Specifically, the data processing module 410 receives image signals (such as R, G, and B signals) from an external graphics controller (not shown). The data processing module 410 appropriately processes the image signal to generate the scan control signal and the data control signal.

The signal correction module 420 receives the correction signal provided by the processing module 630 and corrects the scanning control signal and the data control signal processed by the data processing module 410 according to the correction signal.

The scan driver 200 generates a corrected scan voltage based on the corrected scan control signal and applies the corrected scan voltage to the plurality of scan lines G₁ to Gₙ.

The data driver 300 generates a corrected data voltage based on the corrected data control signal and applies the corrected data voltage to the plurality of data lines D₁ to Dₘ.

The corrected scan voltage and the corrected data voltage are configured to keep the display of each of the plurality of pixels PX unchanged before and after bending.

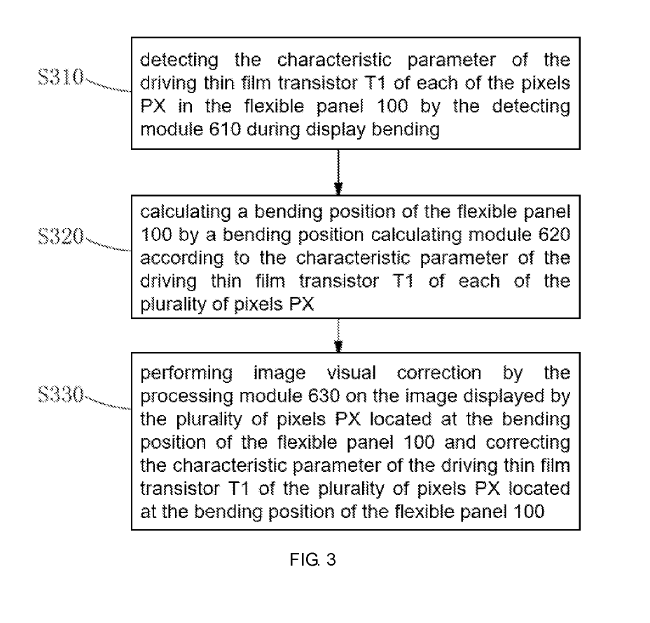

FIG. 3 is a flow chart of an improving method of bending display abnormality of a flexible display according to an embodiment of the disclosure.

Referring to FIG. 3, an improving method of bending display abnormality of a flexible display according to an embodiment of the disclosure includes the steps S310 to S360.

Referring to FIGS. 1 to 3, in step S310, the detecting module 610 is configured to detect the characteristic parameter of the first thin film transistor T1 of each of the pixels PX in the flexible panel 100 during the bending display. Specifically, the detecting module 610 is configured to detect the gate voltage and/or a mobility of the first thin film transistor T1 of each of the pixels PX in the flexible panel 100 during the bending display.

In step S320, the bending position calculating module 620 is configured to calculate a bending position of the flexible panel according to the characteristic parameter (that is, the gate voltage and/or a mobility detected by detecting module 610) of the first thin film transistor T1 of each of the plurality of pixels PX.

In step S330, the processing module 630 is configured to perform image visual correction on the image displayed by the plurality of pixels PX located at the bending position of the flexible panel 100 and to correct the characteristic parameter of the first thin film transistor T1 of the plurality of pixels PX located at the bending position of the flexible panel 100. Specifically, the processing module 630 performs image sharpening processing on the image displayed by the plurality of pixels PX located at the bending position of the flexible panel 100, and the processing module further corrects the mobility and/or the channel width-to-length ratio and/or the equivalent capacitance of the first thin film transistor T1 of the plurality of pixels PX located at the bending position of the flexible panel 100 so as to keep the display of each of the plurality of pixels PX unchanged before and after bending.

In summary, according to the embodiments of the disclosure, when the flexible display is displayed in a bent state, the pixels located at the bending positions are corrected to improve the display abnormality, thereby enhancing the display quality.

While the disclosure has been particularly shown and described with reference to exemplary embodiments thereof, it will be understood by those skilled in the art that various changes in form and details may be made therein without departing from the spirit and scope of the disclosure as defined by the appended claims.

What is claimed is:

1. An improving method of bending display abnormality of a flexible display, comprising the following steps:
detecting a characteristic parameter of a driving thin film transistor of each of pixels in a flexible panel during display bending;
calculating a bending position of the flexible panel according to the characteristic parameter of the driving thin film transistor of each of the pixels;
performing image visual correction on an image displayed by the pixels located at the bending position of the flexible panel and correcting the characteristic parameter of the driving thin film transistor of the pixels located at the bending position of the flexible panel.

2. The improving method according to claim 1, wherein a specific method of implementing the step of “performing image visual correction on an image displayed by the pixels located at the bending position of the flexible panel” comprises: performing image sharpening processing on the image displayed by the pixels located at the bending position of the flexible panel.

3. The improving method according to claim 1, wherein a specific method for implementing the step of “correcting the characteristic parameter of the driving thin film transistor of the pixels located at the bending position of the flexible panel” comprises: correcting a mobility and/or a channel width-to-length ratio and/or an equivalent capacitance of the driving thin film transistor of the pixels located at the bending position of the flexible panel.

4. The improving method according to claim 2, wherein a specific method for implementing the step of “correcting the characteristic parameter of the driving thin film transistor of the pixels located at the bending position of the flexible panel” comprises: correcting a mobility and/or a channel width-to-length ratio and/or an equivalent capacitance of the driving thin film transistor of the pixels located at the bending position of the flexible panel.

5. The improving method according to claim 1, wherein a specific method for implementing the step of “detecting a characteristic parameter of a driving thin film transistor of each of pixels in the flexible panel during display bending” comprises: detecting a gate voltage and/or a mobility of the driving thin film transistor of each of the pixels in the flexible panel during display bending.

6. An improving device of bending display abnormality of a flexible display, comprising:
a detecting module, configured to detect a characteristic parameter of a driving thin film transistor of each of pixels in a flexible panel during display bending;
a bending position calculating module, configured to calculate a bending position of the flexible panel according to the characteristic parameter of the driving thin film transistor of each of the pixels; and
a processing module, configured to perform image visual correction on an image displayed by the pixels located at the bending position of the flexible panel and correcting the characteristic parameter of the driving thin film transistor of the pixels located at the bending position of the flexible panel.

7. The improving device according to claim 6, wherein the processing module is further configured to perform image sharpening processing on the image displayed by the pixels located at the bending position of the flexible panel.

8. The improving device according to claim 6, wherein the processing module is further configured to correct a mobility and/or a channel width-to-length ratio and/or an equivalent capacitance of the driving thin film transistor of the pixels located at the bending position of the flexible panel.

9. The improving device according to claim 7, wherein the processing module is further configured to correct a mobility and/or a channel width-to-length ratio and/or an equivalent capacitance of the driving thin film transistor of the pixels located at the bending position of the flexible panel.

10. The improving device according to claim 6, wherein the detecting module is further configured to detect a gate voltage and/or a mobility of the driving thin film transistor of each of the pixels in the flexible panel during display bending.

11. A flexible display, comprising:
a flexible panel comprising a plurality of pixels, wherein the plurality of pixels comprises a driving thin film transistor and an organic light emitting diode connected to the driving thin film transistor;
a power voltage generator, configured to provide a positive power voltage to the driving thin film transistor and provide a negative power voltage to the organic light emitting diode;
the improving device according to claim 6, configured to correct the plurality of pixels located at the bending position of the flexible panel so as to generate a correction signal during display bending of the flexible panel;
a timing controller, configured to correct a scan control signal and a data control signal generated by the timing controller according to the correction signal;
a scan driver, configured to generate a corrected scan voltage based on a corrected scan control signal and to supply the corrected scan voltage to the plurality of pixels;
a data driver, configured to generate a corrected data voltage based on a corrected data control signal and to supply the corrected data voltage to the plurality of pixels.

12. The flexible display according to claim 11, wherein the plurality of pixels further comprises a second thin film transistor, a third thin film transistor, a storage capacitor, a read line, and a switch control line;
a source of the driving thin film transistor is connected to an anode of an organic light emitting diode, a drain of the driving thin film transistor is connected to the power voltage generator to receive the positive power voltage; a gate of the driving thin film transistor is connected to a drain of the second thin film transistor; a cathode of the organic light emitting diode is connected to the power voltage generator to receive the negative power voltage; a gate of the second thin film transistor is connected to a scan line and a source of the second thin film transistor is connected to a data line; the storage capacitor is connected between the source and the gate of the driving thin film transistor; and a gate of the third thin film transistor is connected to the switch control line, a source of the third thin film transistor is connected to the read line, a drain of the third thin film transistor is connected to the source of the driving thin film transistor, and the read line is connected to the improving device.
